(19) United States
(12) Patent Application Publication
(10) Pub. No.: US 2021/0035851 A1
(43) Pub. Date: Feb. 4, 2021

(54) LOW CONTACT AREA SUBSTRATE SUPPORT FOR ETCHING CHAMBER

(71) Applicant: APPLIED MATERIALS, INC., Santa Clara, CA (US)

(72) Inventors: CHANGHUN LEE, SAN JOSE, CA (US); MICHAEL D. WILLWERTH, CAMPBELL, CA (US); JEFFREY LUDWIG, SAN JOSE, CA (US)

(21) Appl. No.: 16/526,840

(22) Filed: Jul. 30, 2019

(51) Int. Cl. H01L 21/687; H01L 21/67

(52) U.S. Cl. CPC H01L 21/68785; H01L 21/68742; H01L 21/67103

(57) ABSTRACT

Embodiments of a substrate support for use in a processing chamber are provided herein. In some embodiments, a substrate support includes a pedestal having an upper surface configured to accommodate a lift pin, a first annular region near an edge of the pedestal, and a second annular region disposed between the first annular region and a center of the pedestal, wherein the pedestal includes a first plurality of holes extending from the upper surface at regular intervals along the first annular region and a second plurality of holes extending from the upper surface at regular intervals along the second annular region; and a non-metal ball comprising aluminum oxide disposed in each hole of the first plurality of holes and the second plurality of holes, wherein an upper surface of each of the non-metal balls is raised with respect to the upper surface of the pedestal to define a support surface.

### FIELD

Embodiments of the present disclosure generally relate to semiconductor processing equipment.

### BACKGROUND

Substrate supports are typically used in semiconductor processing chambers to support a substrate being processed. A type of substrate support can include a heated pedestal to provide thermal coupling to the substrate during processing, such as for an etching process. However, a high substrate contact area with the pedestal can lead to particle contamination of a backside of the substrate, scratching of the substrate, or substrate breakage due to sticking of the substrate to the substrate support.

Accordingly, the inventors have provided embodiments of improved substrate supports.

### SUMMARY

Embodiments of substrate supports for use in a processing chamber are provided herein. In some embodiments, a substrate support includes a pedestal having an upper surface configured to accommodate a lift pin, a first annular region near an edge of the pedestal, and a second annular region disposed between the first annular region and a center of the pedestal, wherein the pedestal includes a first plurality of holes extending from the upper surface at regular intervals along the first annular region and a second plurality of holes extending from the upper surface at regular intervals along the second annular region; and a non-metal ball comprising aluminum oxide disposed in each hole of the first plurality of holes and the second plurality of holes, wherein an upper surface of each of the non-metal balls is raised with respect to the upper surface of the pedestal to define a support surface.

In some embodiments, an apparatus for processing a substrate includes a process chamber; and a substrate support assembly at least partially disposed in the process chamber, the substrate support assembly including a first plate having a plurality of non-metal balls extending away from an upper surface of the first plate to define a support surface configured to support a substrate, wherein the plurality of non-metal balls are disposed at regular intervals along a first ring about a center of the first plate and at regular intervals along a second ring concentric with the first ring, a second plate coupled to the first plate, wherein the second plate has an outer diameter greater than an outer diameter of the first plate and a plurality of pins extending upwards from an upper peripheral surface of the second plate, wherein the upper peripheral surface is defined by a portion of the second plate that extends radially outward from an outer sidewall of the first plate; and a shaft coupled to the second plate.

In some embodiments, a process chamber includes a chamber body having an inner volume; a pedestal disposed in the inner volume and having a plurality of non-metal balls comprising an aluminum oxide and extending away from an upper surface of the pedestal to define a support surface configured to support a substrate at an elevated position from the upper surface, wherein the plurality of non-metal balls are disposed at regular intervals along a first ring about a center of the pedestal and at regular intervals along a second ring concentric with the first ring; a lift mechanism having a lift pin that is configured to raise or lower a substrate with respect to the support surface, wherein the lift pin is capable of passing through a recess of the pedestal that extends from an outer sidewall of the pedestal towards the center of the pedestal.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a schematic view of a processing chamber in accordance with some embodiments of the present disclosure.

FIG. 2 depicts an isometric view of a pedestal in accordance with some embodiments of the present disclosure.

FIG. 3 depicts a top view of a pedestal in accordance with some embodiments of the present disclosure.

FIG. 4 depicts a partial cross-sectional view of a pedestal in accordance with some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of substrate supports for use in a processing chamber are provided herein. The substrate support includes a pedestal having an upper surface to support a substrate. The substrate support advantageously includes non-metal elements raised with respect to the upper surface of the pedestal to define a support surface having a low contact area with the substrate when the substrate is placed on the substrate support. The non-metal elements are advantageously positioned to provide a low contact area for the substrate while providing for adequate thermal coupling to the substrate. A low contact area for the substrate advantageously reduces or prevents substrate scratching, contamination, or sticking.

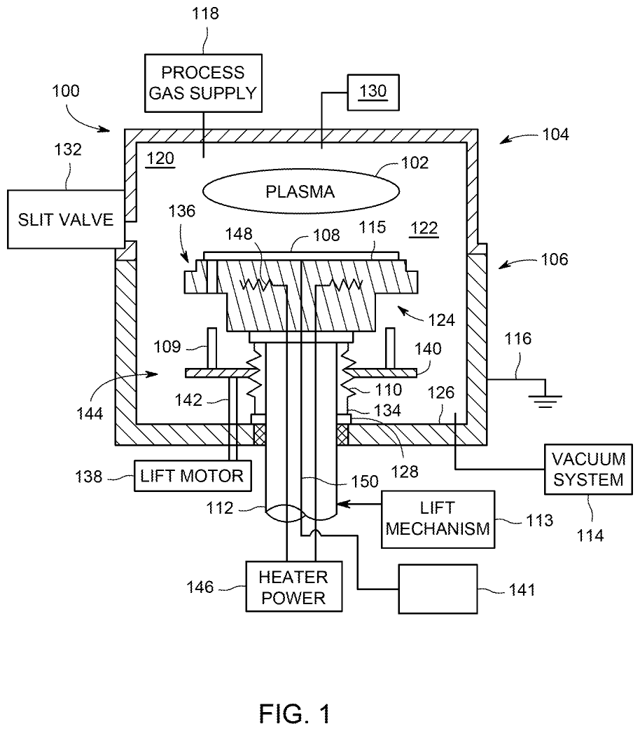

FIG. 1 depicts a schematic side view of a process chamber in accordance with some embodiments of the present disclosure (e.g., a plasma processing chamber). In some embodiments, the plasma processing chamber is an etch processing chamber. However, other types of processing chambers configured for different processes can also use or be modified for use with embodiments of the substrate support described herein.

The chamber 100 is a vacuum chamber which is suitably adapted to maintain sub-atmospheric pressures within a chamber interior volume 120 during substrate processing. The chamber 100 includes a chamber body 106 covered by a lid 104 which encloses a processing volume 122 located in the upper half of chamber interior volume 120. The chamber 100 may also include one or more shields circumscribing various chamber components to prevent unwanted reaction between such components and ionized process material. The chamber body 106 and lid 104 may be made of metal, such as aluminum. The chamber body 106 may be grounded via a coupling to ground 116.

A substrate support 124 is disposed within the chamber interior volume 120 to support and retain a substrate 108, such as a semiconductor wafer, for example, or other such substrate. The substrate support 124 may generally comprise a pedestal 136 and a hollow support shaft 112 for supporting the pedestal 136. In some embodiments, the pedestal 136 is a circular piece of aluminum. The hollow support shaft 112 provides a conduit to provide, for example, backside gases, process gases, vacuum chucking, fluids, coolants, power, or the like, to the pedestal 136. In some embodiments, a slit valve 132 is coupled to at least one of the chamber body 106 and the lid 104 to facilitate transfer of the substrate 108 into and out of the chamber 100.

In some embodiments, the hollow support shaft 112 is coupled to a lift mechanism 113, such as an actuator or motor, which provides vertical movement of the pedestal 136 between a processing position (as shown in FIG. 1) and transfer position (not shown). A bellows assembly 110 is disposed about the hollow support shaft 112 and is coupled between the pedestal 136 and a bottom surface 126 of chamber 100 to provide a flexible seal that allows vertical motion of the pedestal 136 while preventing loss of vacuum from within the chamber 100. The bellows assembly 110 also includes a lower bellows flange 128 in contact with an o-ring or other suitable sealing element which contacts the bottom surface 126 to help prevent loss of chamber vacuum.

A substrate lift 144 can include lift pins 109 mounted on a platform 140 connected to a shaft 142 which is coupled to a second lift mechanism 138 for raising and lowering the substrate lift 144 so that the substrate 108 may be placed on or removed from the pedestal 136. In some embodiments, the platform 140 has a hoop shape. In some embodiments, the platform 140 has a hoop shape and the lift pins 109 extend radially inwards from the platform 140. The pedestal 136 may include thru-holes or recesses to receive the lift pins 109.

The chamber 100 is coupled to and in fluid communication with a vacuum system 114 which includes a throttle valve (not shown) and vacuum pump (not shown) which are used to exhaust the chamber 100. The pressure inside the chamber 100 may be regulated by adjusting the throttle valve and/or vacuum pump. The chamber 100 is also coupled to and in fluid communication with a process gas supply 118 which may supply one or more process gases to the chamber 100 for processing a substrate disposed therein. In some embodiments, the substrate support 124 includes a conduit 150 extending from an upper surface 115 of the pedestal 136 to a vacuum system 141. In some embodiments, the vacuum system 141 comprises a vacuum pump configured to provide vacuum chucking at the upper surface 115 of the pedestal 136.

A temperature of the pedestal 136 may be adjusted to control the temperature of the substrate. For example, the pedestal 136 may be heated using one or more heating elements 148 that are embedded, such as a resistive heater. The one or more heating elements 148 are coupled to a heater power supply 146 to provide power to the one or more heating elements 148.

In operation, for example, a plasma 102 may be created in the chamber interior volume 120 to perform one or more processes. The plasma 102 may be created by coupling power from a plasma power source (e.g., RF plasma power supply 130) to a process gas via one or more electrodes near or within the chamber interior volume 120 to ignite the process gas and creating the plasma 102.

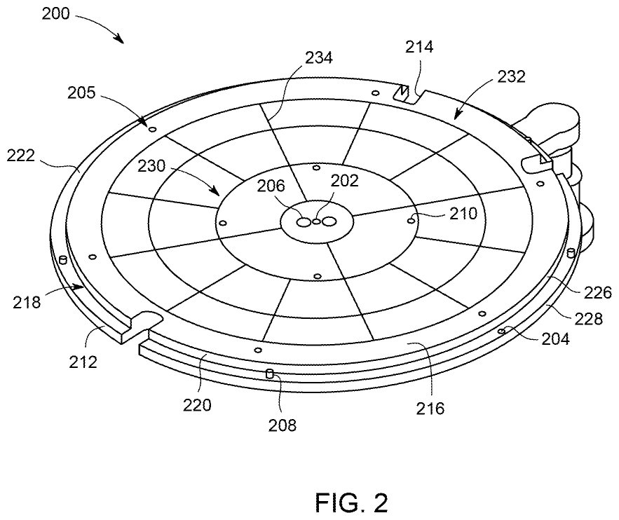

FIG. 2 depicts an isometric view of a pedestal in accordance with some embodiments of the present disclosure. The pedestal 200 may be pedestal 136 as described with respect to FIG. 1. In some embodiments, the pedestal 200 includes a first plate 226 disposed on and coupled to a second plate 228. In some embodiments, the first plate 226 defines an upper portion and the second plate 228 defines a lower portion of the pedestal 200. In some embodiments, the first plate 226 is brazed to the second plate 228. The first plate 226 of the pedestal 200 includes an upper surface 216 configured to support a substrate. In some embodiments, the second plate 228 is coupled to the hollow support shaft 112.

In some embodiments, the first plate 226 has a diameter less than a diameter of the second plate 228 to create a notch 218 at an upper peripheral edge of the pedestal 200. The notch 218 is defined by an upper peripheral surface 222 of the second plate 228 and an outer sidewall 220 of the first plate 226. In some embodiments, the upper peripheral surface 222 is defined by a portion of the second plate 228 that extends radially outward from the outer sidewall 220 of the first plate 226. In some embodiments, a lip is defined by a portion of the second plate 228 that extends radially outward from the first plate 226.

The pedestal 200 includes a first annular region 232 near an edge of the pedestal 200 and a second annular region 230 disposed between the first annular region 232 and a center of the pedestal 200. In some embodiments, the pedestal 200 includes a central opening 202 at the center of the pedestal. The central opening 202 may be fluidly coupled to conduit 150. In some embodiments, one or more openings 206 are disposed adjacent the central opening 202. The one or more openings 206 are configured to receive a fastener to couple the pedestal 200 to other components of the substrate support 124. In some embodiments, the upper surface 216 includes grooves 234 having a suitable pattern to provide vacuum chucking. In some embodiments, the upper surface 216 does not include grooves 234.

In some embodiments, the pedestal 200 includes one or more recesses 214 extending radially inwards from an outer sidewall 212 of the pedestal 200. In some embodiments, the one or more recesses 214 extend into both the first plate 226 and the second plate 228. The one or more recesses 214 are configured to accommodate one or more lift pins 109. In some embodiments, as shown in FIG. 2, the one or more recesses 214 comprise three recesses 214 to accommodate three lift pins 109. In some embodiments, two recesses 214 of the one or more recesses 214 are closer to each other than a third recess 214.

In some embodiments, the pedestal 200 includes a first plurality of holes 205 extending from the upper surface 216. In some embodiments, the first plurality of holes 205 are disposed at regular intervals along the first annular region 232. In some embodiments, the pedestal 200 includes a second plurality of holes 210 extending from the upper surface 216 at regular intervals along the second annular region 230. In some embodiments, the first plurality of holes 205 are six holes. In some embodiments, the second plurality of holes 210 is four holes.

In some embodiments, a plurality of pins 208 extend upwards from the upper peripheral surface 222 of the second plate 228. In some embodiments, at least one pin 208 of the plurality of pins 208 is disposed between adjacent recesses 214 of the one or more recesses 214. In some embodiments, a plurality of second holes 204 extend from the upper peripheral surface 222 to at least partially through the second plate 228. In some embodiments, at least one hole 204 of the plurality of second holes 204 is disposed between adjacent pins 208 of the plurality of pins 208. In some embodiments, each hole 204 of the plurality of second holes 204 is disposed between adjacent pins 208 of the plurality of pins 208 In some embodiments, a focus ring is disposed on the upper peripheral surface 222 of the second plate 228 and held in place via the plurality of pins 208 and the plurality of holes 204.

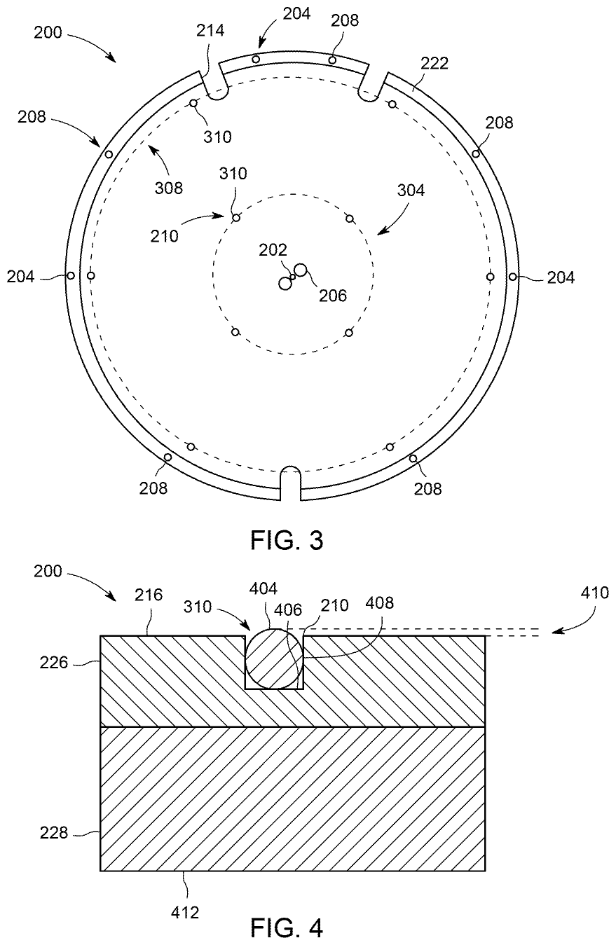

FIG. 3 depicts a top view of a pedestal in accordance with some embodiments of the present disclosure. In some embodiments, the pedestal 200 may include grooves for vacuum chucking (e.g., grooves 234), which are omitted from FIG. 3 for clarity. The pedestal 200 includes a plurality of non-metal elements 310 disposed in each hole of the first plurality of holes 205 and the second plurality of holes 210. The plurality of non-metal elements 310 extend away from the upper surface 216 of the first plate 226 to define a support surface configured to support a substrate. In some embodiments, the plurality of non-metal elements 310 are non-metal balls. In some embodiments, the plurality of non-metal balls 310 are made of aluminum oxide (Al₂O₃) (e.g., sapphire).

In some embodiments, the plurality of non-metal elements 310 in the first plurality of holes 205 are disposed at regular intervals along a first ring 308 about a center of the pedestal 200. In some embodiments, the first ring 308 is about 10.5 inches to about 11.5 inches away from the center of the pedestal. In some embodiments, the plurality of non-metal elements 310 are disposed at regular intervals along a second ring 304 concentric with the first ring. In some embodiments, the second ring 304 is about 4.0 inches to about 5.0 inches away from the center of the pedestal. The plurality of non-metal elements 310 disposed at regular intervals along each of the first ring 308 and the second ring 304 advantageously provide a low contact area between the substrate 108 and the pedestal 200 while providing enough support to reduce or prevent deformation of the substrate 108. The plurality of non-metal elements 310 are advantageously positioned to provide enough support to reduce or prevent deformation of the substrate 108 while providing for adequate thermal coupling to the substrate 108.

FIG. 4 depicts a partial cross-sectional view of a pedestal in accordance with some embodiments of the present disclosure. A lower surface 412 of the second plate 228 can be coupled to the hollow support shaft 112. As shown in FIG. 4, a non-metal element 310 having a spherical shape is disposed in a hole 210 of the second plurality of holes 210. The non-metal element 310 rests on a bottom surface 406 of the hole 210 and fits between sidewalls 408 of the hole 210.

The non-metal element 310 has an upper surface 404 that is raised a distance 410 with respect to the upper surface 216 of the pedestal 200. In some embodiments, the upper surface 404 of the non-metal element 310 is raised a distance 410 of about 0.005 inches to about 0.015 inches from the upper surface 216 of the pedestal 200. In some embodiments, the hole 210 has a diameter slightly smaller than a diameter of the non-metal element 310. In some embodiments, the non-metal element 310 has a diameter of about 0.10 inches to about 0.20 inches.

While the foregoing is directed to embodiments of the present disclosure, other and further embodiments of the disclosure may be devised without departing from the basic scope thereof.

1. A substrate support, comprising:
a pedestal having an upper surface configured to accommodate a lift pin, a first annular region near an edge of the pedestal, and a second annular region disposed between the first annular region and a center of the pedestal, wherein the pedestal includes a first plurality of holes extending from the upper surface at regular intervals along the first annular region and a second plurality of holes extending from the upper surface at regular intervals along the second annular region; and
a non-metal ball comprising aluminum oxide disposed in each hole of the first plurality of holes and the second plurality of holes, wherein an upper surface of each of the non-metal balls is raised with respect to the upper surface of the pedestal to define a support surface.

2. The substrate support of claim 1, further comprising a heating element disposed in the pedestal.

3. The substrate support of claim 1, wherein the first plurality of holes are six holes.

4. The substrate support of claim 3, wherein each of the non-metal balls disposed in the first plurality of holes are about 10.5 inches to about 11.5 inches away from the center of the pedestal.

5. The substrate support of claim 1, wherein the second plurality of holes is four holes.

6. The substrate support of claim 5, wherein each of the non-metal balls disposed in the second plurality of holes are about 4.0 inches to about 5.0 inches away from a center of the pedestal.

7. The substrate support of claim 1, further comprising a second recess and a third recess extending radially inward from an outer sidewall of the pedestal to accommodate a second lift pin and a third lift pin, respectively.

8. The substrate support of claim 1, wherein the pedestal includes an upper portion and a lower portion and a lip extending radially outward from the lower portion of the pedestal.

9. The substrate support of claim 1, wherein the upper surface of the non-metal ball is raised about 0.005 inches to about 0.015 inches from the upper surface of the pedestal.

10. The substrate support of claim 1, wherein the upper surface includes a recess extending radially inward from an outer sidewall configured to accommodate the lift pin.

11. An apparatus for processing a substrate, comprising:
a process chamber; and
a substrate support assembly at least partially disposed in the process chamber, the substrate support assembly comprising:
a first plate having a plurality of non-metal balls extending away from an upper surface of the first plate to define a support surface configured to support a substrate, wherein the plurality of non-metal balls are disposed at regular intervals along a first ring about a center of the first plate and at regular intervals along a second ring concentric with the first ring,
a second plate coupled to the first plate, wherein the second plate has an outer diameter greater than an outer diameter of the first plate and a plurality of pins extending upwards from an upper peripheral surface of the second plate, wherein the upper peripheral surface is defined by a portion of the second plate that extends radially outward from an outer sidewall of the first plate; and
a shaft coupled to the second plate.

12. The apparatus of claim 11, wherein six non-metal balls are disposed along the first ring and four non-metal balls are disposed along the second ring.

13. The apparatus of claim 12, further comprising a focus ring disposed on the upper peripheral surface of the second plate and held in place via the plurality of pins.

14. The apparatus of claim 11, wherein the non-metal balls are made of sapphire.

15. The apparatus of claim 11, wherein the plurality of non-metal balls extend about 0.005 inches to about 0.015 inches away from the upper surface of the first plate.

16. The apparatus of claim 11, wherein the plurality of non-metal balls have a diameter of about 0.10 inches to about 0.20 inches.

17. A process chamber, comprising:
a chamber body having an inner volume;
a pedestal disposed in the inner volume and having a plurality of non-metal balls comprising an aluminum oxide and extending away from an upper surface of the pedestal to define a support surface configured to support a substrate at an elevated position from the upper surface, wherein the plurality of non-metal balls are disposed at regular intervals along a first ring about a center of the pedestal and at regular intervals along a second ring concentric with the first ring; and
a lift mechanism having a lift pin that is configured to raise or lower a substrate with respect to the support surface, wherein the lift pin is capable of passing through a recess of the pedestal that extends from an outer sidewall of the pedestal towards the center of the pedestal.

18. The process chamber of claim 17, wherein six non-metal balls are disposed along the first ring and four non-metal balls are disposed along the second ring.

19. The process chamber of claim 17, wherein the plurality of non-metal balls have a diameter of about 0.10 inches to about 0.20 inches.

20. The process chamber of claim 17, wherein the first ring is about 10.5 inches to about 11.5 inches away from the center of the pedestal.
